(19) United States
(12) Patent Application Publication
(10) Pub. No.: US 2008/0266990 A1
(43) Pub. Date: Oct. 30, 2008

(54) Flexible redundancy replacement scheme for semiconductor device

(75) Inventor: Steffen Loeffler, Essex Junction, VT (US)

Correspondence Address: POSZ LAW GROUP, PLC, 12040 SOUTH LAKES DRIVE, SUITE 101, RESTON, VA, 20191, US

(73) Assignee: Infineon Technologies North America Corp., San Jose, CA (US)

(21) Appl. No.: 11/790,934

(22) Filed: Apr. 30, 2007

(51) Int. Cl. G11C 7/00

(52) U.S. Cl. 365/201

(57) ABSTRACT

A redundancy replacement scheme for repairing a faulty memory cell including memory cells arranged in memory blocks containing word lines and column select lines. The redundancy replacement scheme including replacing the faulty memory cell in a second memory block with a spare memory cell in the second memory block based on a decoded address of a first memory block.

### BACKGROUND OF THE INVENTION

A memory cell array, such as a Dynamic Random Access Memory (DRAM) array, can be partitioned or divided (logically or physically) into memory banks or row segments. The memory banks or row segments contain groups of memory cells that are arranged in a row-column format. For example, a memory array arranged by rows or word lines (WL) and columns or bit lines (BL) can be further divided by grouping or partitioning a plurality of word lines into row segments. In such an arrangement, a group of bits of word lines that are provided along a column or bit line are segmented from another group of bits of word lines that are provided along the same column or bit line.

Each memory cell is structured for storing digital information in the form of a “1” or a “0” bit. To write (i.e., store) a bit into a memory cell, a memory address having portions identifying the cell's row (the “row address”) and column (the “column address”) is provided to address circuitry in the semiconductor memory to activate the memory cell, and the bit is then supplied to the memory cell. Similarly, to read (i.e., retrieve) a bit from a memory cell, the memory cell is again activated using the cell's memory address, and the bit is then output from the memory cell.

When the memory cells are arranged in row segments or banks, the binary memory address can include a row segment or bank address. For example, if the memory contains a plurality of memory cells arranged together in a segment or block of rows or word lines, the address can include additional bits identifying the row segment or block of the memory cell array to be accessed.

Semiconductor memories are typically tested after they are fabricated to determine if they contain any failing or faulty memory cells (i.e., cells to which bits cannot be dependably written or from which bits cannot be dependably read). Generally, when a semiconductor memory is found to contain failing memory cells, an attempt is made to repair the memory by replacing the failing memory cells with redundant memory cells provided in redundant rows (word lines), redundant columns (bit lines), and/or segmented column lines (segmented bit lines).

When a redundant row is used to repair a semiconductor memory containing a failing memory cell, the failing cell's WL address is permanently stored (typically in predecoded form) on a chip on which the semiconductor memory is fabricated by programming a nonvolatile element (e.g., a group of fuses, antifuses, or FLASH memory cells) on the chip. Then, during normal operation of the semiconductor memory, if the memory's addressing circuitry receives a memory address including a WL address that corresponds to the WL address stored on the chip, redundant circuitry in the memory causes a redundant memory cell in the redundant WL to be accessed instead of the memory cell identified by the received memory address. Since every memory cell in the failing cell's WL has the same WL address, every cell in the failing cell's WL, both operative and failing, is replaced by a redundant memory cell in the redundant row.

Similarly, when a redundant column (bit line) needs to be repaired in the semiconductor memory, the failing cell column is permanently stored (typically in predecoded form) on the chip by programming a nonvolatile element on the chip. Then, during normal operation of the semiconductor memory, if the memory's addressing circuitry receives a memory address including a column address that corresponds to the column address stored on the chip, redundant circuitry in the memory causes a redundant memory cell in the redundant column to be accessed instead of the memory cell data identified by the received memory address. As every memory cell in the failing cell column has the same column address, every cell in the failing cell column, both operative and failing, is replaced by a redundant memory cell in the redundant column.

In current redundancy schemes, a defect in one row segment is corrected by using redundant locations either in the same row segment (intrablock) or in an adjacent row segment (interblock). This type of redundancy offers more options for repairing defects. However, in this type of scheme, the row or WL repair and the column or column select line (CSL) repair are interdependent which results in limited flexibility in repair.

According to the current redundancy scheme, the CSL repair region is selected during WL activation based on the row address. If an addressed WL needs to be replaced (i.e., it contains a faulty memory cell), it can be replaced with a WL within the same block or row segment (i.e., intrablock repair) or outside the block (i.e., interblock repair). If the CSL in the original row segment needs repair, a corresponding or identical CSL repair is made in the row segment into which the defective WL is replaced. The CSL replacement occurs whether or not the CSL in the new row segment is defective. Alternatively, it is possible that the CSL in the original row segment is operative while the CSL in the new row segment is defective. Since the CSL repair region is determined by the row address of the WL requiring repair, the defective CSL in the new row segment will not be repaired, and therefore a fault will occur. This arrangement limits the repair options. For such reasons, the current redundancy scheme limits flexibility in repair.

As a result of the above-described replacement scheme, operative memory cells can be unnecessarily replaced, thereby reducing overall memory yield during production.

### SUMMARY OF INVENTION

A redundancy replacement scheme for a semiconductor device repairing a faulty memory cell in second memory block with a spare memory cell in the second memory block, based on a decoded address of a first memory block.

### BRIEF DESCRIPTION OF THE DRAWINGS

The accompanying figures, where like reference numerals refer to identical or functionally similar elements and which together with a detailed description set forth herein are incorporated in and form part of the specification, serve to further illustrate various exemplary embodiments and to explain various principles and advantages in accordance with this application.

FIG. 1 is a block diagram showing a memory cell array in which certain memory cells within the array are replaced through interblock repair.

FIG. 2 is a block diagram showing a replacement scheme for repairing a memory array such as that shown in FIG. 1.

FIG. 3 is a flow diagram illustrating a procedure for repairing a memory array.

FIG. 4 is a block diagram showing a semiconductor memory device including a replacement scheme.

FIG. 5 is a block diagram showing a row segment decoder.

FIG. 6 is a block diagram showing a column select line repair circuit.

### DESCRIPTION OF THE PREFERRED EMBODIMENTS

The following exemplary embodiments and aspects thereof are described and illustrated in conjunction with structures and methods that are meant to be exemplary and illustrative, and not limiting in scope. In the following description, numerous specific details are set forth, such as representative memory addresses, to provide a thorough understanding of the present invention. However, it will be obvious to those skilled in the art that the embodiments described in this application can be practiced without such specific, but exemplary, details. In other embodiments, circuits have been shown in block diagram form in order not to obscure the embodiments described in this application in unnecessary detail. For the most part, details concerning timing considerations, the arrangement of sense amplifiers, transistors, storage capacitors, data lines and the like have been omitted inasmuch as such details are not necessary to obtain a complete understanding of the embodiments described in this application.

It is contemplated that memory repair schemes can be used to repair defective memory cells in DRAMs. However, the memory repair schemes described herein can also be used in SDRAM (synchronous DRAM), SRAM (static random access memory), as well as stand alone RAM (random access memory) and other types of memory devices.

The memory cells are arranged by word lines (WL) and columns or bit lines (BL), thereby forming a memory cell array. In this application, the terms “word line” or “WL” will be used interchangeably with the term “row.” The term “column” is interchangeable with the expression “bit line” or “BL.”

An embodiment of the present application is concerned with a WL and column repair scheme in which the column repair is independent of WL repair, such as where column select lines (CSL) are replaced by redundant column select lines.

In the redundant replacement schemes described in the embodiments of this application, the column select line repair region need not be selected based on the original row address, but is selected based on the select signal of the row segment actually used for WL repair or replacement. As a result, overall memory yield is increased, as CSL repair is based on the physical, not logical, address of a row segment address, so that good or properly functioning memory cells are not wasted.

FIG. 1 represents a memory array divided into word lines, represented by vertical lines, and columns, represented by horizontal lines. The word lines are grouped in segments or blocks identified by “Row Segment 3,” “Row Segment 2,” “Row Segment 1,” and “Row Segment 0.” While four row segments are shown, a larger or smaller number of row segments can be used, as understood by those skilled in the art, depending on the size and configuration of the memory array, as desired. Many memory cells are connected to each of the word lines and columns. A memory cell is arranged at the intersection or crossover points of each of the word lines and columns. Each row segment includes word lines and column segments. In FIG. 1, MC designates a memory cell generally, and MX designates a defective or faulty memory cell. While only a few word lines, columns and column segments are shown for ease of illustration and discussion, a larger number of word lines, columns and column segments can be used, as understood by those skilled in the art, depending on the size and configuration of the memory array, as desired.

Representative word lines are identified by reference numerals 125 and 140, and representative columns are identified by reference numerals 25 and 40. The word lines extend vertically, while the columns extend horizontally. Columns 25, 40 can extend horizontally across the entire memory array. In FIG. 1, a dotted line represents a normal word line, such as WL 120, containing normally addressable memory cells or units. A dashed line represents a defective or faulty word line (WL) associated with a defective are failing memory cell or a defective or faulty column segment. For example, WL 125 is defective. For convenience and ease of illustration, a column select lines (CSLs) associated with a column segment are shown as 3-25, 3-40, 2-25 and 2-40. A short and long dashed line (line with shorter and longer dashes) represents a redundant word line (WL) or a redundant column select line (CSL). For example, 140 is a redundant WL, and 2-40 is a redundant CSL.

The column select lines are divided by row segments 3, 2, 1 and 0. For example, 3-25 and 3-40 identify column select lines in row segment 3, while 2-25 and 2-40 identify CSLs in row segment 2. The areas in FIG. 1 below the redundant CSLs (i.e., 3-40) and outside of or before the redundant word lines (i.e., 140) in each of the row segments 3, 2, 1 and 0 contain addressable normal memory cells combined to form normally addressable units. For example, the dotted WL line portion 120 represents a normally addressable unit of memory cells.

A defective memory cell MX in a column segment associated with a CSL (i.e., defective CSL) can be replaced or remapped by replacing the defective CSL with a redundant CSL. Each time a defective CSL is addressed, a redundancy circuit, which can be included in a CSL repair circuit, activates the spare element or redundant CSL selected by an address programmed into the nonvolatile storage device or element (i.e., fuses) during production testing. A defective WL containing a defective or failing memory cell MX can be replaced by spare elements (i.e., redundant word lines) either within the same row segment or in any other row segment. The replacement of a WL in the same row segment (i.e., row segment 3, row segment 2, row segment 1 or row segment 0) is an intrablock (intrasegment) repair, while a replacement between different row segments is called an interblock (intersegment) repair. An interblock repair is shown by arrow A in FIG. 1. Fuses programmed during production tests determine which replacement scheme is to be used.

In the case of an interblock WL repair, where the WL, column and CSL addresses are used interdependently, errors can occur. This can happen when a WL replacement utilizes a redundant WL in a row segment having a CSL that needs to be replaced. For example, when making a repair for a row segment (i.e., row segment 3), the CSL repair region or segment is based on the row segment address and is active only for that row segment (i.e., row segment 3). If the redundant WL and thus active WL is in row segment 2 (i.e., by remapping or repair), the CSL repair will not take place when the WL and CSL repairs are interrelated or the addresses used therefor are interrelated. This is because the CSL repair circuit does not decode a match in row segment 2. This will cause fails that appear to be in row segment 3.

In other words, during a combined WL and CSL interdependent repair, a defective WL 125 is repaired via an interblock repair from one row segment into another row segment (i.e., from row segment 3 into row segment 2, as shown by arrow A). In this situation, CSL 2-25, which corresponds to a logically defective CSL 3-25, is replaced by a spare element or redundant CSL 2-40. This type of repair can cause the spare or redundant CSL 2-40 to become activated in segment 2 even when the original CSL 2-25 was passing (good). Also, in such an interdependent repair, the entire memory will fail if the spare or redundant CSL 2-40 in row segment 2 has a fail.

For example, assuming that a column select line repair was necessary for CSL 3-25 in row segment 3 and the CSL repair is based on the row segment address for row segment 3, an interdependent repair will cause the CSL replacement identified by arrow B to occur in row segment 2. Namely, the CSL corresponding to CSL 3-25 (i.e., 2-25) would be replaced by the CSL 2-40 in row segment 2. However, if a memory cell (MC) associated with corresponding CSL 2-40 was defective or faulty, the memory would fail. On the other hand, if the corresponding MC in a column segment corresponding to CSL 2-25 was a good or properly functioning memory cell, the CSL replacement identified by arrow B would not be necessary and such an interdependent repair or replacement would defeat the function of replacing bad or faulty bits or memory cells with good or properly functioning memory cells and prohibit the use of CSL 2-40 for another CSL repair, thereby limiting yield.

A flexible word line/column select line repair scheme provides for defective word line repair via interblock repair (arrow A), where any CSL repairs necessary along the redundant WL 140 will be based on the fact that the active (physical) WL is in row segment 2, rather than the fact that the logical address for WL 125 is in row segment 3. With the arrangement according to this embodiment of the application, no precaution is needed when deriving the repair solution, and the repair flexibility is not limited.

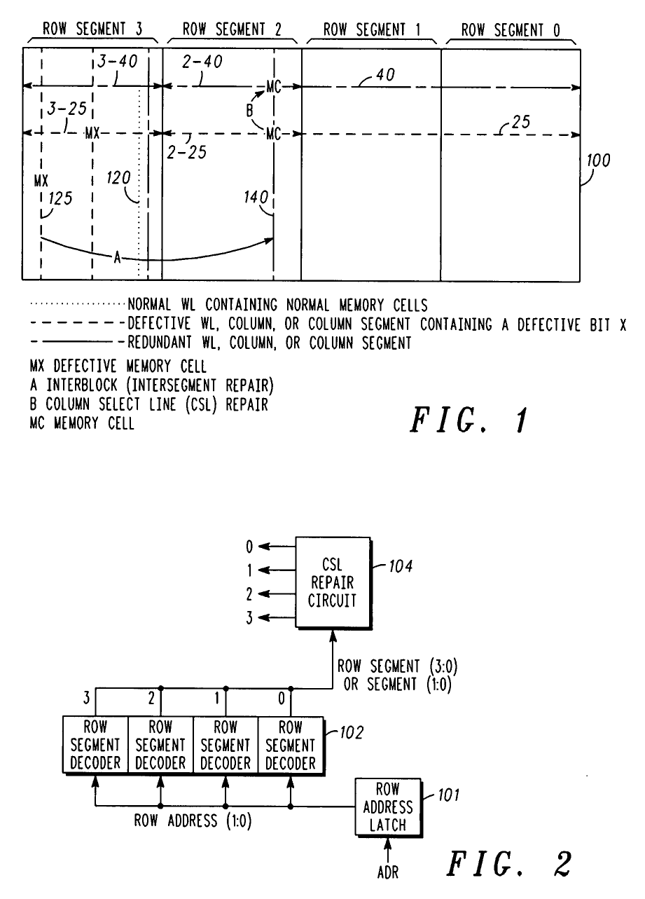

In the arrangement shown in FIG. 2, row segment addresses are decoded and used for CSL decode. The row segment decoder 102 (shown, for example, as four separate boxes in FIG. 2) decodes each row segment address signal (i.e., row address 3:0) received from the row address latch 101. In the arrangement shown in FIG. 2, the row address is decoded, and if a match corresponding to a defective WL is found that is replaced with a redundant WL in another row segment, a decoded row address segment (i.e., 1:0) is output from the row signal decoder 102, which identifies the other row segment address. If no match is found, the decoded row segment address (i.e. 3:0) will match the input row segment address (i.e. 3:0).

Decoded row segment signals from the row segment decoder 102 are sent to the CSL repair circuit 104 and are used as CSL repair region select signals. In this embodiment, the CSL repair is decoupled (separated) from the WL repair. This can be termed a “decoupled interblock repair.” No timing penalty is incurred with this arrangement, since the tRCD (row (WL) addressed to column address delay) is sufficiently long to transmit the decoded row segment information back into the CSL repair circuit 104.

In the decoupled interblock repair, a defective WL in a first row segment (first memory block) is repaired with a redundant WL in a second row segment (second memory block), the row segment address associated with the defective WL is decoded, and the decoded row segment address is used for CSL repair in the second row segment. The repair is decoupled in that the row segment address is decoded and the decoded address is used for CSL repair. In contrast, in the interdependent repair an address received by the memory is used for redundancy repair based on the initial relationship between the row segment address, row address and column address of the address received. Namely, in the interdependent repair the redundancy repair in the second row segment is based on the initial (logical) address of the first row segment, not the physical (decoded) address of the second row segment as described herein for the decoupled interblock repair.

A flow diagram illustrating a procedure for repairing a memory array according to an embodiment of this application is shown in FIG. 3. The procedure starts by receiving a memory address along a bus. In step 401, a defective word line in a first memory block is identified based on a word line address. The defective word line in the first memory block (or first row segment), as identified in step 401, is remapped to or replaced by a redundant word line in a second memory block (or second row segment) in step 402. In step 403, the address for the first memory block is decoded to a physical address for the second memory block. In step 404, a defective column select line in the second memory block is remapped to or repaired with the a redundant column select line in the second memory block based on the physical (not logical) address of the second memory block, as identified in step 403. The procedure then ends.

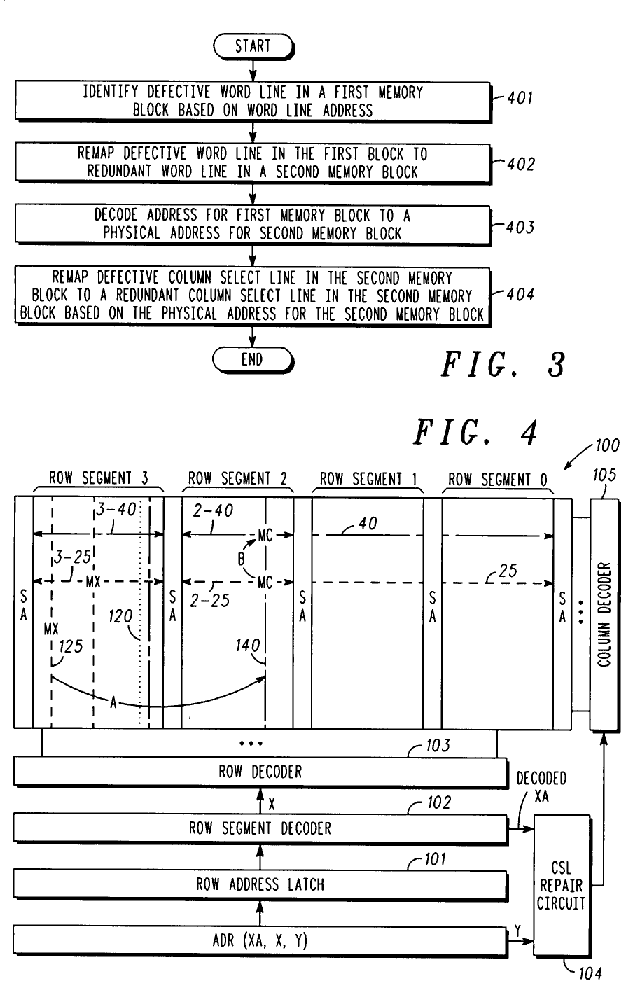

FIG. 4 is an expanded view of the semiconductor memory device 100 shown in FIG. 1. FIG. 4 is equipped with the decoupled interblock repair and includes a feature in that a column select line (CSL) repair circuit receives not only a column address that identifies the column (i.e., Y), but also a row segment address that identifies the decoded row segment XA. FIG. 4 shows sense amplifiers (SA) strips arranged vertically on opposite sides of each row segment 3, 2, 1 and 0. These and the additional structures shown in FIG. 4 were omitted from FIG. 1 for brevity.

In the semiconductor device 100 shown in FIG. 4, an address (ADR) is received by the row address latch 101 from an address bus. The ADR includes a row segment address XA, a WL address that identifies a word line (i.e., X) and a column address (i.e., Y). The ADR is passed from the row address latch 101 to the row segment decoder 102.

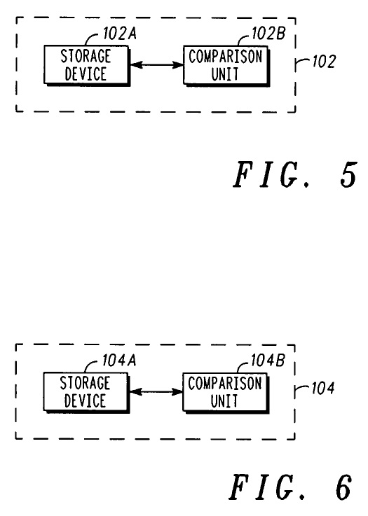

The row segment decoder 102 includes a redundancy circuit having storage device 102A and comparison unit 102B, as shown in FIG. 5. The storage device 102A stores, in a normal or precoded mode, an address for one of the memory cells that needs to be replaced by one of the redundant memory cells in, for example, a redundant unit (i.e., 140, 2-40). The comparison unit 102B of row segment decoder 102, which is connected to the storage device 102A of the row segment decoder 102, compares a received address with an address stored in the storage device 102A and redirects memory access to the redundant unit in the event a match is identified. The storage device 102A can be nonvolatile storage device, such as a plurality of fuse fuses, antifuses, or FLASH memory cells.

As mentioned above, in addition to a WL address (i.e., X) supplied to the row decoder 102, a row segment address (i.e. XA) that can identify the logical level of the most significant bits of the row segment address is also supplied to the row segment decoder 102. The row segment address XA identifies the logical level of the most significant bits of the row segment address, for which a binary address can be “00” or “01” or “10” or “11” and which are used to identify row segments 0, 1, 2 and 3. In other words, the XA address can be the most significant bits of the ADR.

The row segment decoder 102 decodes the row segment address corresponding to the redundant WL used for the WL repair. The decoded row segment address and the column address are supplied to the CLS repair circuit 104 (CLS repair region decoder), which supplies the column address to the column decoder 105. The column decoder 105 activates the column address in response to the column address (i.e., Y) received from the CSL repair circuit 104.

In the embodiment shown in FIG. 4, the CSL repair circuit 104 detects the supply of the row segment address corresponding to a defective memory cell in a column segment associated with a particular CSL. The CSL repair circuit 104 can include a plurality of fuse elements or other nonvolatile storage unit, and store the XA and Y addresses (typically in normal or precoded form) corresponding to a defective CSL according to whether or not these fuses are blown. When an address corresponding to a defective word line in a first row segment (i.e., 125) is supplied to the row segment decoder 102, the row segment decoder 102 decodes the row segment address of the redundant word line in the second row segment (i.e., 140) that will replace the defective WL and sends the XA address for the redundant word line to the CSL repair circuit 104.

The CSL repair circuit 104 can include a redundancy circuit. The redundancy circuit can include storage device 104A and comparison unit 104B, as shown in FIG. 6. The comparison unit 104B, which is connected to the storage device 104A, compares an address, such as the row segment address, that is received from the row segment decoder 102 with an address stored in the storage device 104A contained in the CSL repair circuit 104. The comparison unit 104B activates one of the redundant units (i.e. redundant CSL) in the event a match is identified. The comparison unit 104B of the CSL repair circuit 104 compares the row segment address XA of the redundant word line 140 to the stored row segment addresses and column addresses in the storage device 104A corresponding to defective column select lines. When a match is detected, the CSL corresponding to the row segment address XA of the redundant word line is replaced with a redundant CSL. The storage device 104A is a nonvolatile storage device, such as a plurality of fuse fuses, antifuses, or FLASH memory cells.

For example, if the stored row segment address and column address for a particular CSL were not stored in the CSL repair circuit 104 (namely, the CSL is not defective), the CSL repair circuit 104 will not replace the CSL. Thus, if CSL 2-25 corresponding to redundant WL 140 was not defective (the addresses for CSL 2-25 were not stored in the CSL repair circuit 104), it would not be replaced. On the other hand, if CSL 2-25 was defective (the addresses for CSL 2-25 are stored in the CSL repair circuit 104), it would be replaced by, for example, redundant CSL 2-40. The arrangements of this embodiment of the present application assure that only defective CSLs are repaired or replaced. In addition, the arrangements of this embodiment of the present application allow greater flexibility for WL and CSL repair, because good and properly functioning CSLs are not replaced, thereby freeing unused redundant CSLs for replacement of other defective CSLs.

In view of the above, it will be seen that the embodiments of the invention are achieved and other advantageous results attained. As various changes could be made in the above constructions without departing from the scope of the flexible redundancy replacement scheme for memory described in this application, it is intended that all matter contained in the above description or shown in the accompanying drawings shall be interpreted as illustrative and not in a limiting sense.

What is claimed is:

1. A method for repairing a faulty memory cell in a semiconductor device, where memory cells are arranged in memory blocks containing word lines and column select lines, the method comprising:
replacing the faulty memory cell in a second memory block with a spare memory cell in the second memory block based on a decoded address of a first memory block.

2. The method for repairing a faulty memory cell in a semiconductor device according to claim 1, wherein the decoded address of the first memory block corresponds to a physical address of the second memory block.

3. The method for repairing a faulty memory cell in a semiconductor device according to claim 1, wherein addresses for defective column select lines are stored in a storage device based on a memory block address and a column address.

4. The method for repairing a faulty memory cell according to claim 3, wherein a decoded address of the first memory block is compared to the addresses stored in the memory for the second memory block.

5. The method for repairing a faulty memory cell in a semiconductor device according to claim 1, wherein the column select lines are replaced based upon the physical addresses for the second memory block.

6. A method for replacing a faulty memory cell with a redundant memory cell in a memory array, comprising:
decoding a row segment address for a word line and obtaining a decoded row segment address; and
remapping the faulty memory cell in one row segment based on the decoded row segment address.

7. The method for repairing a faulty memory cell with a redundant memory cell according to claim 6, wherein the remapping includes comparing the decoded row segment address and a column address with stored addresses identifying faulty memory cells by a row segment address and a column address.

8. The method for repairing a faulty memory cell with a redundant memory cell according to claim 6, wherein the decoded row segment address and a column address are sent to a column select line repair circuit.

9. The method for repairing a faulty memory cell with a redundant memory cell according to claim 6, wherein column select lines are replaced based upon a physical row address for each row segment.

10. The method for repairing a faulty memory cell with a redundant memory cell according to claim 6, comprising:
receiving an address containing a row segment address, a word line address, and a column address in a row address latch;
supplying the address to a row segment decoder, the row segment decoder decoding the row segment address and matching a redundant row segment address thereto and supplying the redundant row segment address to a column select line repair circuit; and
the column select line repair circuit performing column select line repair based upon a physical address of the redundant row segment address.

11. A combination comprising:
replacement means for replacing a defective memory cell in a memory array that is arranged by word lines and columns, the word lines being partitioned into memory blocks identified by row segments, in which a defective word line in a first memory block containing the defective memory cell is replaced with a redundant word line in a second memory block; and
the replacement means including decoding means for decoding and identifying the defective memory cell in a word line of the first memory block based on a row segment address for the first memory block address and repairing a column select line associated with a defective memory cell in the second memory block with a redundant column select line in the second memory block based on the decoded row segment address for the first block memory address.

12. The combination according to claim 11, wherein the decoding means includes storage means for storing column select line addresses and column addresses corresponding to defective memory cells.

13. The combination according to claim 11, wherein the decoding means includes comparison means coupled to storage means for comparing input addresses to the row segment line addresses and column addresses stored in the storage means and outputting an address for the redundant column select line when a match occurs between the an input address and the row segment addresses and column addresses stored in the storage means.

14. The combination according to claim 11, wherein the decoding means includes row segment decoder means for decoding a row segment address for a defective word line in a first row segment, column select line repair means for receiving the decoded row segment address and activating the redundant column select line in a second row segment based on the decoded row segment address of the defective word line in the first row segment.

15. The combination according to claim 11, wherein the decoding means replaces column select lines based upon a physical row address for each row segment.

16. A semiconductor memory device, comprising:
a plurality of word lines grouped in row segments, the row segments respectively containing a redundant word line and a redundant column select line;
a row segment decoder decoding a row segment address for a defective word line in a first row segment; and
a column select line circuit receiving the decoded row segment address and activating a column select line of a second row segment based on the decoded row segment address of the defective word line in the first row segment.

17. The semiconductor memory device according to claim 16, wherein column select lines are replaced based upon a physical row segment address for each column row segment.

18. The semiconductor memory device according to claim 16, wherein an address containing a row segment address, a word line address, and a column address is received by a row address latch and fed to the row segment decoder, wherein the column address is fed to a column select decoder; the row segment decoder decoding the row segment address and matching a redundant row segment address thereto and feeding the redundant row segment address to the column select line circuit; the column select line circuit performing column select line repair based upon a physical address of the redundant row segment address.

19. A semiconductor memory device, comprising:
a plurality of memory cells in a memory cell array, the memory cells being combined to form individually addressable units;
a plurality of redundant units of memory cells for respectively replacing one of the units on an address basis;
a first storage device to store an address for any unit that needs to be replaced by one of the redundant units;
a first comparison unit coupled to the first storage device to compare an input address with an address stored in the first storage device and to activate one of the redundant units when a match is identified;
a second storage device to store another address for any unit that needs to be repaired; and
a second comparison unit coupled to the second storage device to compare the address of the activated one of the redundant units with the another address stored in the second storage device and to activate another one of the redundant units when a match is identified.

20. The semiconductor memory device according to claim 19, further comprising a row address latch to receive an address containing a row segment address, a word line address, and a column address and to supply the received address to the first comparison unit, wherein the column address is supplied to the second comparison unit; the first comparison unit comparing the row segment address and matching a redundant row segment address thereto and supplying the redundant row segment address to the second comparison unit; and the second comparison unit performing column select line repair based upon a physical address of the redundant row segment address.
